(19) United States
(12) Patent Application Publication
(10) Pub. No.: US 2014/0057212 A1
(43) Pub. Date: Feb. 27, 2014

(54) TRANSMISSION APPARATUS, DRAWING APPARATUS, AND METHOD OF MANUFACTURING ARTICLE

(71) Applicant: CANON KABUSHIKI KAISHA, Tokyo (JP)

(72) Inventors: Shinji OHISHI, Oyama-shi (JP); Kimitaka OZAWA, Utsunomiya-shi (JP); Go TSUCHIYA, Tochigi-shi (JP)

(73) Assignee: CANON KABUSHIKI KAISHA, Tokyo (JP)

(21) Appl. No.: 13/970,652

(22) Filed: Aug. 20, 2013

(30) Foreign Application Priority Data
Aug. 22, 2012 (JP) 2012-183591

(51) Int. Cl. H01J 37/30; F21V 8/00

(52) U.S. Cl. CPC H01J 37/3007; G02B 6/0005
USPC 430/325; 362/551; 250/396 R

(57) ABSTRACT

The present invention provides a transmission apparatus for transmitting a light signal between an outside and an inside of a vacuum chamber, comprising a plurality of first transmission lines configured to transmit a plurality of light signals outside the vacuum chamber, a plurality of second transmission lines configured to transmit the plurality of light signals inside the vacuum chamber, and a light-transmissive member configured to transmit the light signals between the plurality of first transmission lines and the plurality of second transmission lines, wherein the light-transmissive member has a structure formed to isolate light paths of the plurality of light signals between the plurality of first transmission lines and the plurality of second transmission lines from each other.

### BACKGROUND OF THE INVENTION

1. Field of the Invention

The present invention relates to a transmission apparatus, a drawing apparatus including the same, and a method of manufacturing article.

2. Description of the Related Art

Along with the progress in microfabrication and integration of circuit patterns in semiconductor integrated circuits, a drawing apparatus that draws a pattern on a substrate using a plurality of charged particle beams (electron beams) has received attention. Since the drawing apparatus performs drawing on the substrate by each charged particle beam in a vacuum chamber, it is necessary to transmit light signals used to control the drawing from the outside of the vacuum chamber to the inside while maintaining the air-tightness of the vacuum chamber. Each of Japanese Patent Laid-Open Nos. 10-319238 and 2002-115054 proposes a transmission apparatus that transmits light signals from the outside of a vacuum chamber to the inside through the partition of the vacuum chamber while maintaining the air-tightness of the vacuum chamber.

Japanese Patent Laid-Open No. 10-319238 proposes a transmission apparatus that includes a plurality of atmosphere-side optical fibers and a plurality of vacuum-side optical fibers, and inserts a glass plate between each atmosphere-side optical fiber and a corresponding vacuum-side optical fiber. Japanese Patent Laid-Open No. 2002-115054 proposes a transmission apparatus that inserts a plurality of optical fibers for transmitting light signals into a through-hole of a vacuum chamber and fills the gap between the through-hole and the optical fibers with an adhesive material.

In recent years, the drawing apparatus is required to improve the throughput. To meet this requirement, the number of charged particle beams is dramatically increasing. Such a drawing apparatus includes, for example, a plurality of blanking deflectors for individually blanking charged particle beams. An enormous number of light signals to control the plurality of blanking deflectors are transmitted into the vacuum chamber through a number of optical fibers (transmission lines). However, when the transmission apparatus described in Japanese Patent Laid-Open No. 10-319238 uses a number of optical fibers, the interval between the plurality of optical fibers is hard to narrow because a glass plate is inserted for each optical fiber, and this may lead to an increase in the size of the transmission apparatus. In the transmission apparatus described in Japanese Patent Laid-Open No. 2002-115054, it may be difficult to maintain the air-tightness of the vacuum chamber due to aging degradation of the adhesive material.

### SUMMARY OF THE INVENTION

The present invention provides a technique advantageous in transmitting light signals into a vacuum chamber through a number of transmission lines.

According to one aspect of the present invention, there is provided a transmission apparatus for transmitting a light signal between an outside and an inside of a vacuum chamber, comprising: a plurality of first transmission lines configured to transmit a plurality of light signals outside the vacuum chamber; a plurality of second transmission lines configured to transmit the plurality of light signals inside the vacuum chamber; and a light-transmissive member configured to transmit the light signals between the plurality of first transmission lines and the plurality of second transmission lines, wherein the light-transmissive member has a structure formed to isolate light paths of the plurality of light signals between the plurality of first transmission lines and the plurality of second transmission lines from each other.

Further aspects of the present invention will become apparent from the following description of exemplary embodiments with reference to the attached drawings.

### BRIEF DESCRIPTION OF THE DRAWINGS

FIG. 1 is a view showing the arrangement of a drawing apparatus according to the first embodiment;

FIG. 2 is a view showing a method of transmitting drawing data by an optical fiber in the first embodiment;

FIG. 3 is a sectional view showing a transmission apparatus according to the first embodiment;

FIG. 4 is a perspective view showing the transmission apparatus according to the first embodiment;

FIGS. 5A, 5B, and 5C are views showing the light path of the optical fiber;

FIGS. 6A and 6B are sectional views showing a light-transmissive member according to the first embodiment;

FIGS. 7A to 7D show views illustrating a method of manufacturing the light-transmissive member according to the first embodiment;

FIGS. 8A to 8D show views illustrating another method of manufacturing the light-transmissive member according to the first embodiment; and

FIG. 9 is a sectional view showing a transmission apparatus according to the second embodiment.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

### First Embodiment

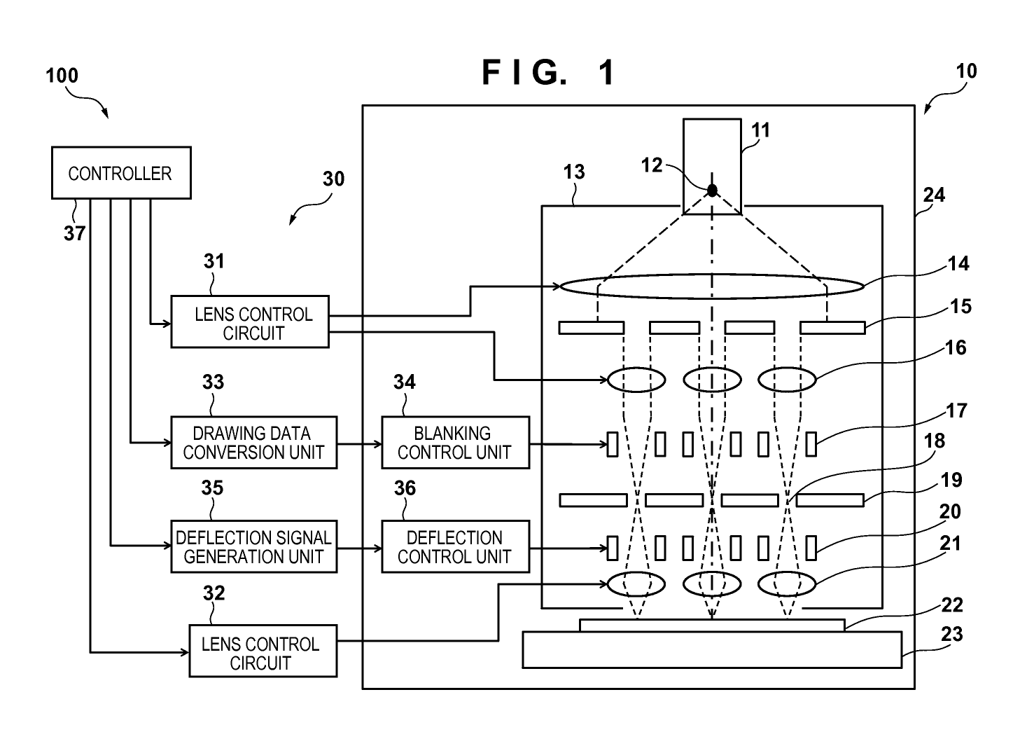

A drawing apparatus 100 using charged particle beams according to the first embodiment of the present invention will be described with reference to FIG. 1. The drawing apparatus 100 using charged particle beams includes a drawing unit 10 that draws a pattern by irradiating a substrate with charged particle beams, and a data processing system 30 that controls the respective units of the drawing unit 10. The drawing unit 10 includes a charged particle gun 11, a charged particle optical system 13, and a substrate stage 23, and is located inside a vacuum chamber 24 (chamber) set in a high-vacuum environment. The charged particle optical system 13 includes, for example, a collimator lens 14, an aperture array 15, first electrostatic lenses 16, blanking deflectors 17, a blanking aperture 19, deflectors 20, and second electrostatic lenses 21.

A charged particle beam emitted by the charged particle gun 11 forms a crossover image 12, changes to a parallel beam by the effect of the collimator lens 14, and enters the aperture array 15. The aperture array 15 has a plurality of openings arranged in a matrix. The charged particle beam that has entered as the parallel beam is thus divided into a plurality of beams. The charged particle beams divided by the aperture array 15 enter the first electrostatic lenses 16. The charged particle beams that have passed through the first electrostatic lenses 16 form intermediate images 18 of the crossover image 12. The blanking aperture 19 having openings located in a matrix is installed on the plane where the intermediate images 18 are formed. The blanking deflectors 17 used to individually control blanking of the plurality of charged particle beams are installed between the first electrostatic lenses 16 and the blanking aperture 19. The charged particle beams deflected by the blanking deflectors 17 are shielded by the blanking aperture 19 and do not reach a substrate 22. That is, the blanking deflectors 17 switch between irradiation and non-irradiation of the substrate 22 with the charged particle beams. The charged particle beams that have passed through the blanking aperture 19 form, through the deflectors 20 and the second electrostatic lenses 21 which are used to scan the charged particle beams on the substrate 22, the images of the crossover image 12 on the substrate 22 held on the substrate stage 23. The deflector 20 preferably deflects the charged particle beam in a direction perpendicular to the scan direction of the substrate stage 23. However, the deflection direction of the charged particle beam is not limited to the direction perpendicular to the scan direction of the substrate stage 23, and the charged particle beam may be deflected to another angle.

The data processing system 30 includes, for example, lens control circuits 31 and 32, a drawing data conversion unit 33, a blanking control unit 34, a deflection signal generation unit 35, a deflection control unit 36, and a controller 37. The lens control circuits 31 and 32 control the lenses 13, 17, and 21. The drawing data conversion unit 33 converts design data supplied from the controller 37 into drawing data used to perform blanking control of the charged particle beams. The blanking control unit 34 is included inside the vacuum chamber 24 and controls the blanking deflectors 17 based on the drawing data supplied from the drawing data conversion unit 33. The deflection signal generation unit 35 generates a deflection signal from the design data supplied from the controller 37 and supplies the deflection signal to the deflection control unit 36 via a deflection amplifier (not shown). The deflection control unit 36 is included inside the vacuum chamber 24 and controls the deflectors 20 based on the deflection signal. The controller 37 supplies the design data to the drawing data conversion unit 33 and the deflection signal generation unit 35 and controls the whole drawing operation.

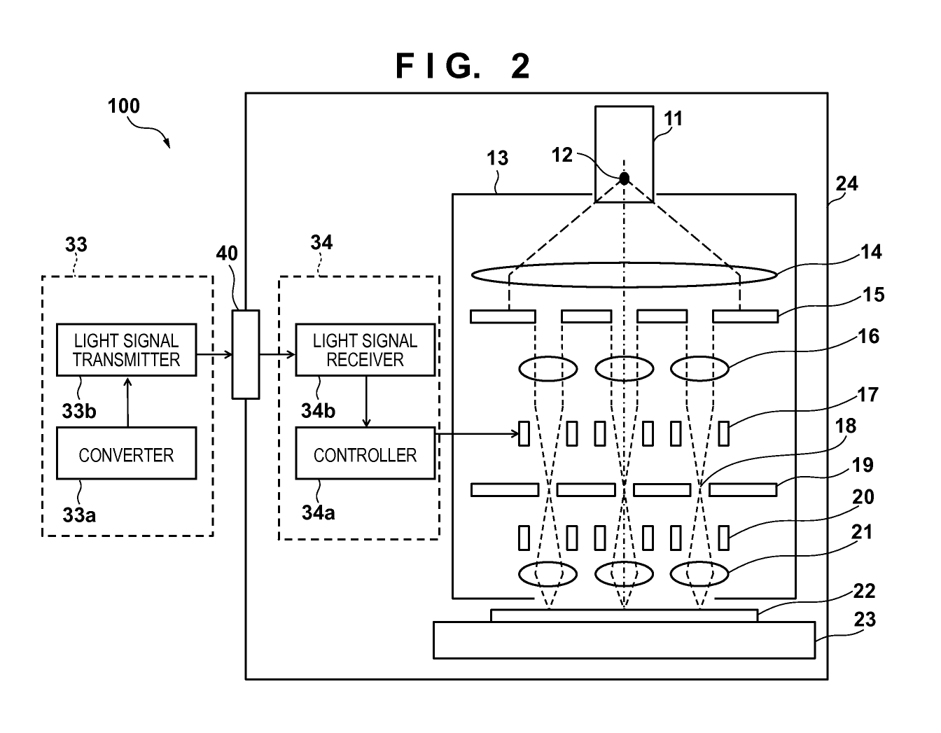

In recent years, the drawing apparatus is required to improve the throughput. To meet this requirement, the number of charged particle beams is dramatically increasing. For this reason, the amount of data to individually control the plurality of charged particle beams is enormous. This data needs to be transmitted to the charged particle optical system 13 at a high speed. For example, assume that the charged particle beam emitted by the charged particle gun 11 is divided into several tens of thousands to several hundreds of thousands of charged particle beams by the aperture array 15, and the charged particle beams undergo blanking control by the individual blanking deflectors 17. When performing blanking control of such several tens of thousands to several hundreds of thousands of charged particle beams by the blanking deflectors 17, an enormous size of drawing data generated by the drawing data conversion unit 33 needs to be transmitted to the blanking control unit 34 at a high speed. To transmit the enormous size of drawing data at a high speed, an optical fiber hardly affected by electromagnetically induced noise and capable of long-distance data transmission is effective for use as a transmission line to transmit the drawing data. A method of transmitting drawing data from the drawing data conversion unit 33 to the blanking control unit 34 by an optical fiber will be described with reference to FIG. 2. The drawing data conversion unit 33 is located outside the vacuum chamber 24 and includes a converter 33a and a light signal transmitter 33b. The converter 33a converts design data supplied from the controller 37 into drawing data. The light signal transmitter 33b transmits the drawing data converted by the converter 33a to the blanking control unit 34 through an optical fiber as a light signal. The blanking control unit 34 is located inside the vacuum chamber 24 and includes a controller 34a and a light signal receiver 34b. The light signal receiver 34b receives the light signal transmitted from the drawing data conversion unit 33 through the optical fiber and converts the received light signal into drawing data. The controller 34a controls the blanking deflectors 17 based on the drawing data. When transmitting the light signal into the vacuum chamber through the optical fiber in the above-described way, the air-tightness of the vacuum chamber 24 needs to be maintained. For this reason, the drawing apparatus 100 according to the first embodiment includes a transmission apparatus 40 for transmitting the light signal into the vacuum chamber while maintaining the air-tightness of the vacuum chamber 24.

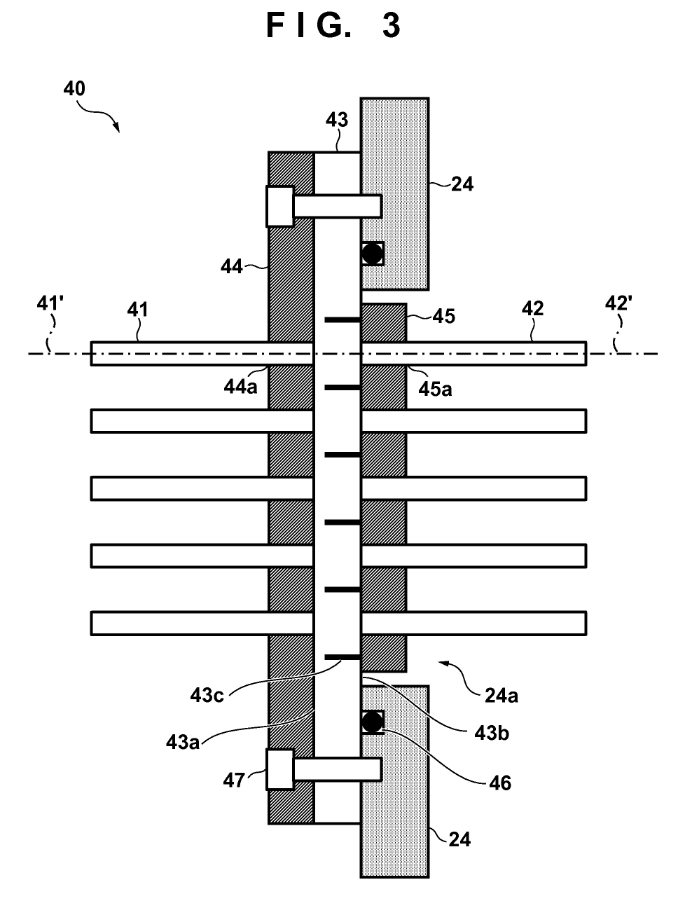

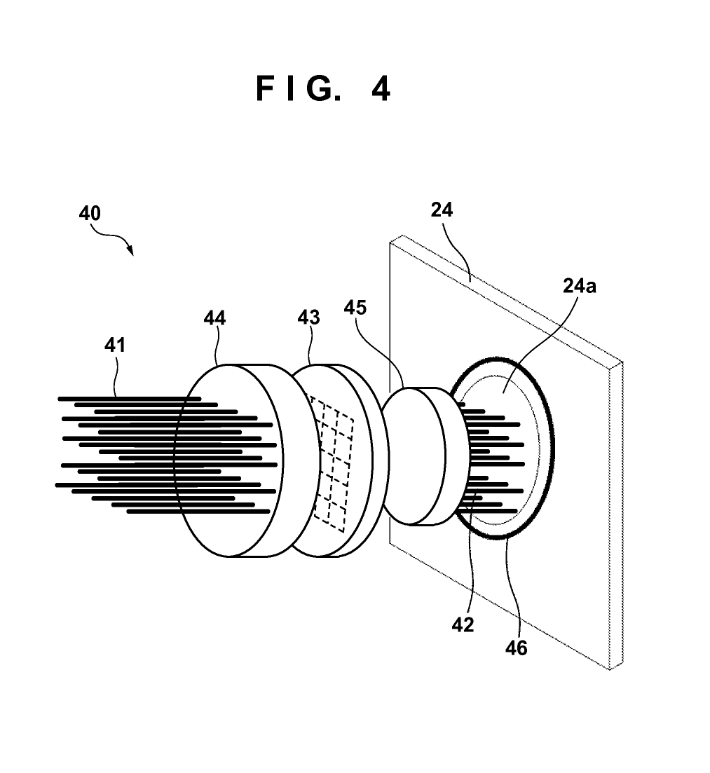

The transmission apparatus 40 in the drawing apparatus 100 according to the first embodiment will be described with reference to FIGS. 3 and 4. FIG. 3 is a sectional view showing the transmission apparatus 40. FIG. 4 is a perspective view showing the transmission apparatus 40. The transmission apparatus 40 includes a plurality of first transmission lines 41 for transmitting light signals outside the vacuum chamber 24, and a plurality of second transmission lines 42 for transmitting light signals inside the vacuum chamber 24. The transmission apparatus 40 also includes a light-transmissive member 43 for transmitting light signals between the plurality of first transmission lines 41 and the plurality of second transmission lines 42. The transmission apparatus 40 also includes a first fixing member 44 for fixing the plurality of first transmission lines 41 to the light-transmissive member 43, and a second fixing member 45 for fixing the plurality of second transmission lines 42 to the light-transmissive member 43. In the transmission apparatus 40 according the first embodiment, each of the plurality of first transmission lines 41 and the plurality of second transmission lines 42 is formed from an optical fiber.

A through-hole 24a is formed in the partition of the vacuum chamber 24 of the drawing apparatus 100 to transmit the light signals between the inside and the outside of the vacuum chamber 24. The through-hole 24a is covered with the light-transmissive member 43 larger than it. The first fixing member 44 having almost the same size as the light-transmissive member 43 is fixed to an atmosphere-side surface 43a of the light-transmissive member 43 using an adhesive material or the like. The first fixing member 44 and the light-transmissive member 43 are attached together to the partition of the vacuum chamber 24 by screws 47 while inserting a sealing member 46 such as an O-ring between them. A plurality of holes 44a are formed in the first fixing member 44 at a predetermined interval. The first transmission lines 41 are respectively inserted in the holes 44a and fixed. The first transmission lines 41 are thus connected to the atmosphere-side surface 43a of the light-transmissive member 43. On the other hand, the second fixing member 45 smaller than the through-hole 24a of the vacuum chamber 24 is fixed to a vacuum-side surface 43b of the light-transmissive member 43 using an adhesive material or the like. A plurality of holes 45a are formed in the second fixing member 45 at a predetermined interval. The second transmission lines 42 are respectively inserted in the holes 45a and fixed. The second transmission lines 42 are thus connected to the vacuum-side surface 43b of the light-transmissive member 43. Each first transmission line 41 and a corresponding second transmission line 42 are located such that a central axis 41′ of the first transmission line 41 and a central axis 42′ of the corresponding second transmission line 42 are aligned. This makes it possible to suppress attenuation of the light signal caused by the misalignment between the first transmission line 41 and the second transmission line 42 and efficiently transmit the light signal between the first transmission line 41 and the second transmission line 42. The light-transmissive member 43 is formed from a member of silica glass or a plastic whose refractive index is almost the same as that of the core portion of the optical fiber. The light-transmissive member 43 has a structure formed to isolate the light paths of the plurality of light signals between the plurality of first transmission lines 41 and the plurality of second transmission lines 42 from each other. The light-transmissive member 43 according to the first embodiment has trenches 43c as the structure. In FIG. 4, the trenches 43c are formed into a lattice-like shape. However, not the lattice-like shape but a circular or hexagonal shape may also be formed. The trenches 43c formed in the light-transmissive member 43 will be described here together with the light path (mode) of the optical fiber.

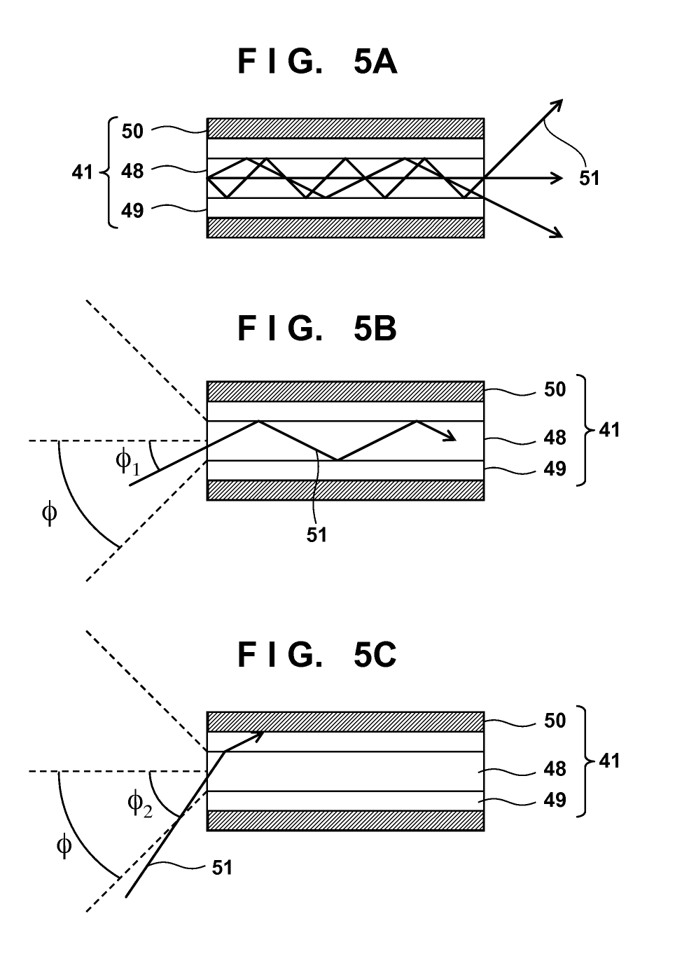

The light path of the optical fiber will be explained first with reference to FIGS. 5A to 5C. FIG. 5A is a view showing the light path of a step index multimode optical fiber. The optical fiber (first transmission line 41) has a three-layer structure including a core 48 that transmits light, a cladding 49 on the outer side of the core, and a coating 50 that covers them. The core 48 and the cladding 49 are made of silica glass or a plastic having a very high transmittance of light. In the optical fiber, the refractive index of the core 48 is set to be higher than that of the cladding 49 so that incident light is totally reflected by the interface between the core 48 and the cladding 49 and propagates only inside the core 48. The light in the core 48 travels along a light path 51 depending on the angle (incident light) of the incident light. The light exiting from the core 48 disperses at various angles. If an incident angle φ₁ of light is smaller than a critical angle φ, as shown in FIG. 5B, the light travels while repeating total reflection in the core. For this reason, the attenuation amount of the light signal can be decreased, and the light signal can be made to propagate far away. On the other hand, if an incident angle φ₂ of light is larger than the critical angle φ, as shown in FIG. 5C, the light is not totally reflected by the interface between the core 48 and the cladding 49. The light partially enters the cladding 49 and is absorbed by the coating 50. For this reason, the attenuation amount of the light signal increases, and it is therefore difficult to make the light signal propagate far away. The second transmission line 42 is formed from an optical fiber having the same structure as described above.

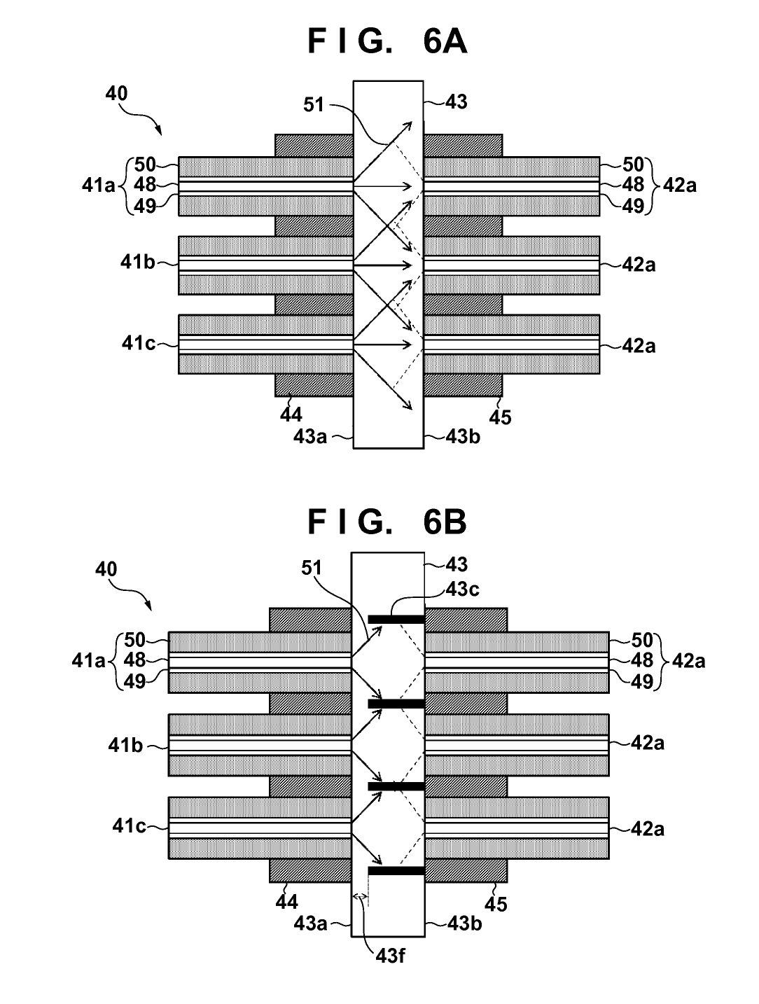

The trenches 43c formed in the light-transmissive member will be described with reference to FIGS. 6A and 6B. FIG. 6A is a view showing the transmission apparatus 40 using the light-transmissive member 43 without the trenches 43c. The first transmission lines 41 (optical fibers) are connected to the atmosphere-side surface 43a of the light-transmissive member 43 by the first fixing member 44. The second transmission lines 42 (optical fibers) are connected to the vacuum-side surface 43b of the light-transmissive member by the second fixing member 45. Note that the vacuum chamber 24, the sealing member 46, and the screws 47 are not illustrated in FIG. 6A. In recent years, the number of charged particle beams is dramatically increasing, as described above. For this reason, the amount of data to individually control the plurality of charged particle beams is enormous, and an enormous number of optical fibers are necessary even if they can transmit data at a high speed. For example, when performing blanking control of 100,000 charged particle beams at 100 MHz, 1,000 optical fibers are necessary to transmit the light signals using optical fibers having a transmission rate of 10 Gbps. When using such an enormous number of optical fibers, it is important to locate the first transmission lines 41 (optical fibers) at a small interval to prevent the transmission apparatus 40 according to the first embodiment from becoming bulky. The light exiting from the first transmission line 41 to the light-transmissive member 43 travels through the light-transmissive member 43 while diverging and enters the second transmission line 42, as shown in FIG. 6A. At this time, if the first transmission lines 41 are located at a narrow interval, the second transmission line 42 receives not only the light signal that should enter the second transmission line 42 but also a light signal that should enter an adjacent second transmission line 42. For example, a central second transmission line 42b of the three second transmission lines 42 shown in FIG. 6A receives not only the light signal exiting from a first transmission line 41b corresponding to the second transmission line 42b but also the light signals exiting from adjacent first transmission lines 41a and 41c. When the light signals exiting from the first transmission lines 41a and 41c enter the second transmission line 42b at an angle smaller than the critical angle φ of the second transmission line 42b, the light signals may be transmitted through the core 48 of the second transmission line 42b. At a result, the light interference occurs in the core 48 of the second transmission line 42b. The quality of the light signal degrades, and it eventually becomes impossible to obtain correct data on the receiving side. To prevent this, in the transmission apparatus 40 according to the first embodiment, the trenches 43c are formed in the light-transmissive member 43, as shown in FIG. 6B. FIG. 6B is a view showing the transmission apparatus 40 using the light-transmissive member 43 with the trenches 43c. The trenches 43c of the light-transmissive member 43 are formed so as to surround the light paths of light signals between the first transmission lines 41 and the corresponding second transmission lines 42. The trenches 43c are formed not to be exposed to the surface on the upstream side (the side of the first transmission lines 41) in the direction to transmit light signals out of the surfaces of the light-transmissive member 43, and also to have a depth in a direction perpendicular to the surface 43b of the light-transmissive member 43 on the second transmission line side. For example, in the first embodiment, the light signal is transmitted from the first transmission line 41 to the second transmission line 42. Hence, the trenches 43c according to the first embodiment are formed from the surface 43b of the light-transmissive member 43 on the second transmission line side to the surface 43a on the first transmission line side such the their depth becomes smaller than the thickness of the light-transmissive member 43. When the trenches 43c are thus formed, a spacing 43f is provided in the light-transmissive member 43 between the trenches 43c and the surface 43a on the first transmission line side. The spacing 43f is provided to reduce the path of air leaking from inside to the outside of the vacuum chamber 24 and maintain the air-tightness of the vacuum chamber 24. The spacing 43f is provided on the side of the first transmission lines 41 because light whose incident angle φ₂ is larger than the critical angle φ is absorbed by the coating 50 of the optical fiber, as shown in FIG. 5C, and the light rarely exists from the first transmission line 41 at an exit angle larger than the critical angle φ. Hence, when the spacing 43f is provided on the side of the first transmission lines 41, the light exiting from the first transmission line rarely leaks from the spacing 43f to the outside. The trenches 43c formed in the light-transmissive member 43 are filled with a light-absorptive material such as a resin. The thus formed trenches 43c can suppress the light signals from the adjacent first transmission lines 41a and 41c from entering the second transmission line 42b. As a result, the second transmission line 42b receives only the light signal of the corresponding first transmission line 41b. It is therefore possible to suppress interference between the light signals and obtain correct data even when the optical fibers are located at a narrow interval. In the first embodiment, the trenches 43c are filled with a light-absorptive material. However, the trenches 43c may be filled with a light-reflecting material that reflects light. Alternatively, the trenches 43c may be unfilled. If the trenches 43c are unfilled, they are filled with the air or set in a vacuum state. Hence, the interface between the air or vacuum and the light-transmissive member 43 can partially reflect light by the difference in the refractive index can cause the reflected light to enter the second transmission line 42. When transmitting the light signal from inside of the vacuum chamber 24 to the outside, the trenches 43c are formed from the surface 43a of the light-transmissive member 43 on the first transmission line side to the surface 43b on the second transmission line side such that their depth becomes smaller than the thickness of the light-transmissive member 43.

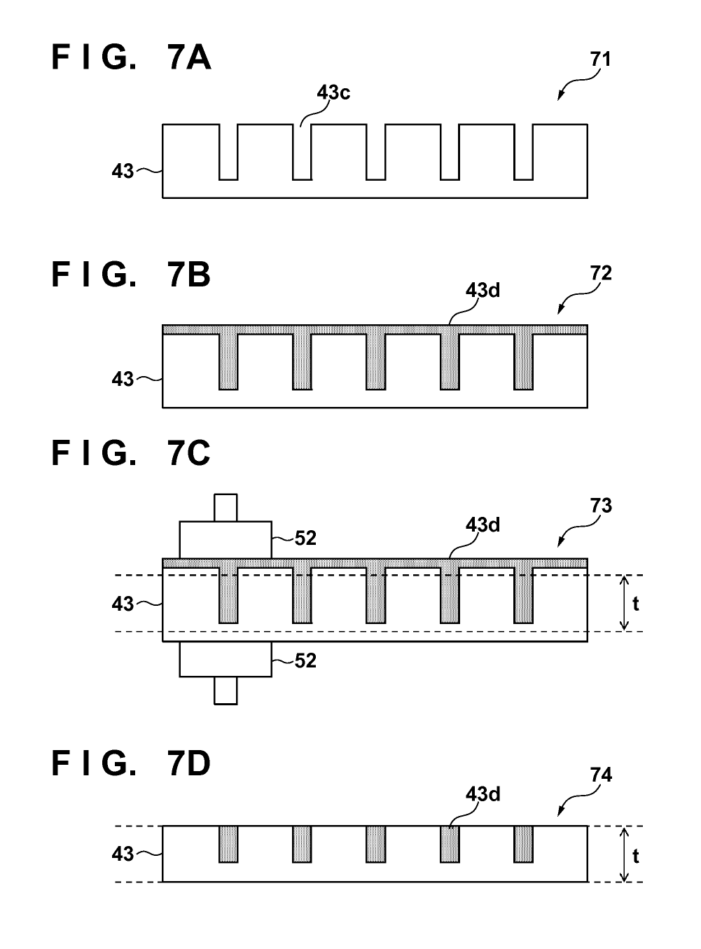

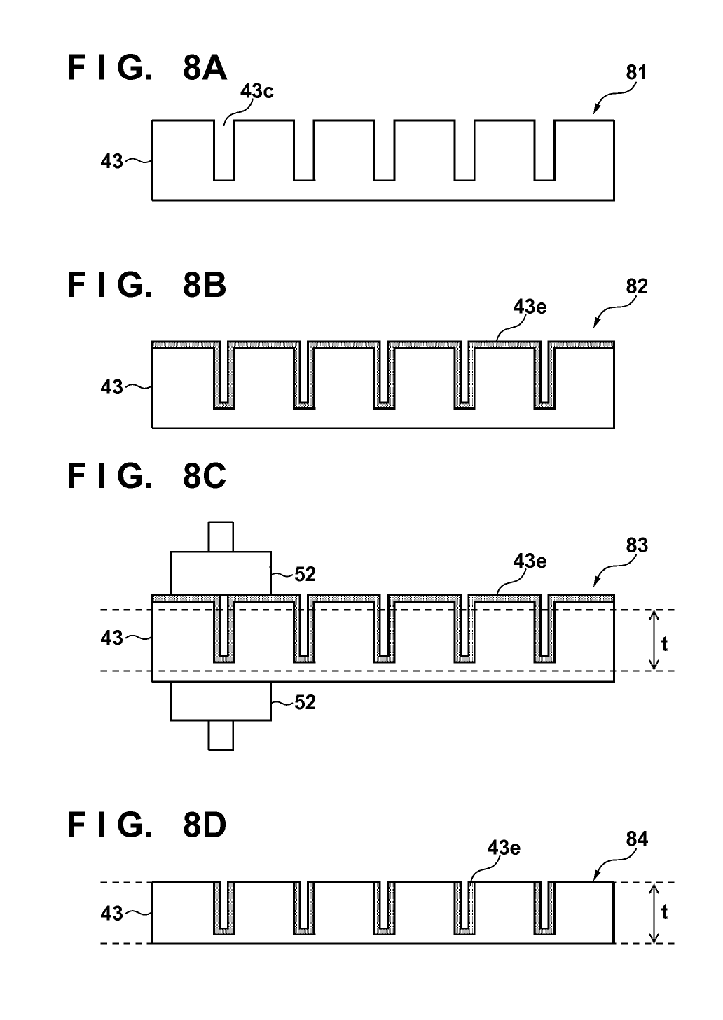

A method of manufacturing the light-transmissive member 43 with the trenches 43c in the transmission apparatus 40 according to the first embodiment will be described with reference to FIGS. 7A to 7D, and FIGS. 8A to 8D. FIGS. 7A to 7D show views illustrating an example of the method of manufacturing the light-transmissive member 43 with the trenches 43c. The light-transmissive member 43 is made of silica glass or a plastic. The trenches 43c having a predetermined depth are formed in the light-transmissive member 43, as indicated by 71 of FIG. 7A. To form the trenches 43c, cutting, laser machining, etching, or the like is used. The trenches 43c formed in the light-transmissive member 43 are filled with a viscous light-absorptive material 43d such as a resin, as indicated by 72 of FIG. 7B. The light-absorptive material 43d is hardened by heat, light, or the like. The light-transmissive member 43 whose trenches 43c are filled with the light-absorptive material 43d is polished and planarized to a predetermined thickness t by a polish pad 52, as indicated by 73 of FIG. 7C. The light-transmissive member 43 is planarized because a light signal is attenuated by a gap formed between the light-transmissive member 43 and the first fixing member 44 or second fixing member 45 when bonding the first fixing member 44 or second fixing member 45 to the light-transmissive member 43. After the planarization, the light-transmissive member 43 having the trenches 43c filled with the light-absorptive material 43d and worked to the predetermined thickness t is obtained, as indicated by 74 of FIG. 7D.

FIGS. 8A to 8D show views illustrating another example of the method of manufacturing the light-transmissive member 43 with the trenches 43c. The light-transmissive member 43 is made of silica glass or a plastic. The trenches 43c having a predetermined depth are formed in the light-transmissive member 43, as indicated by 81 of FIG. 8A. To form the trenches 43c, cutting, laser machining, etching, or the like is used. A film 43e of a light-absorptive material or a metal is formed on the side walls of the trenches 43c formed in the light-transmissive member 43 by, for example, the vacuum deposition method or sputtering method, as indicated by 82 of FIG. 8B. The light-transmissive member 43 in which the film 43e of a light-absorptive material or a metal is formed on the side walls of the trenches 43c is polished and planarized to the predetermined thickness t by the polish pad 52, as indicated by 83 of FIG. 8C. After the planarization, the light-transmissive member 43 having the film 43e of a light-absorptive material or the like formed on the side walls of the trenches 43c and worked to the predetermined thickness t is obtained, as indicated by 84 of FIG. 8D.

As described above, in the transmission apparatus 40 according to the first embodiment, the trenches 43c are formed in the light-transmissive member 43 inserted between the first transmission lines 41 and the second transmission line 42 so as to surround the light paths of light signals transmitted between the first transmission lines 41 and the second transmission lines 42. Each second transmission line 42 receives only the light signal of the corresponding first transmission line 41. It is therefore possible to suppress interference between the light signals and obtain correct data on the light signal receiving side even when the optical fibers are located at a narrow interval.

### Second Embodiment

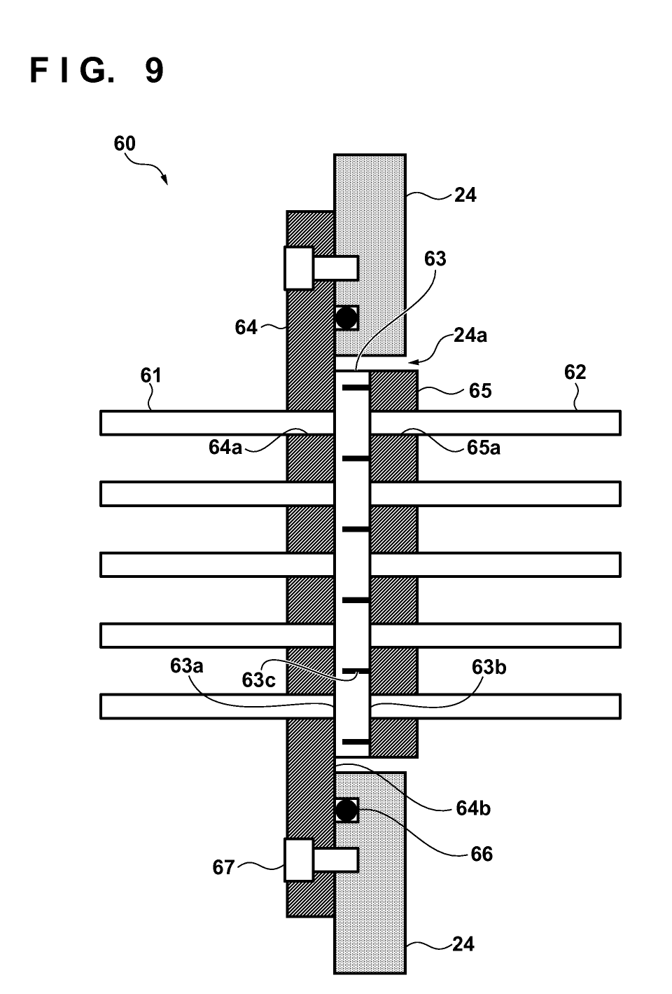

A transmission apparatus 60 according to the second embodiment of the present invention will be described with reference to FIG. 9. In the transmission apparatus 60 according to the second embodiment, the arrangement for attaching the transmission apparatus 60 to the partition of a vacuum chamber 24 is changed by changing the sizes of the members included in the transmission apparatus 60, as compared to the transmission apparatus 40 according to the first embodiment.

FIG. 9 is a sectional view showing the transmission apparatus 60 according to the second embodiment. The transmission apparatus 60 includes a plurality of first transmission lines 61 for transmitting light signals outside the vacuum chamber 24, a plurality of second transmission lines 62 for transmitting light signals inside the vacuum chamber 24, and a light-transmissive member 63 inserted between the plurality of first transmission lines 61 and the plurality of second transmission lines 62. The transmission apparatus 60 also includes a first fixing member 64 for fixing the plurality of first transmission lines 61 to the light-transmissive member 63, and a second fixing member 65 for fixing the plurality of second transmission lines 62 to the light-transmissive member 63. In the transmission apparatus 60 according the second embodiment, each of the plurality of first transmission lines 61 and the plurality of second transmission lines 62 is formed from an optical fiber.

In the second embodiment, a through-hole 24a is formed in the vacuum chamber 24, and the first fixing member 64 larger than the through-hole 24a is attached to the partition of the vacuum chamber 24 by screws 67 or the like while inserting a sealing member 66 such as an O-ring between them. Holes 64a to fix the plurality of first transmission lines 61 are formed in the first fixing member 64 at a predetermined interval. The first transmission lines 61 are respectively inserted in the holes 64a and thus fixed to the first fixing member 64. The light-transmissive member 63 is designed to be smaller than the through-hole 24a and fixed to a vacuum-side surface 64b of the first fixing member 64 by an adhesive material or the like. Trenches 63c are formed in the light-transmissive member 63, as in the light-transmissive member 43 of the first embodiment, thereby suppressing each light signal from entering the second transmission lines 62 adjacent to the target second transmission line 62. The second fixing member 65 having almost the same size as the light-transmissive member 63 is fixed, by an adhesive material or the like, to a surface 63b of the light-transmissive member 63 opposite to a surface 63a fixed to the first fixing member 64. A plurality of holes 65a are formed in the second fixing member 65 at a predetermined interval. When the second transmission lines 62 are respectively inserted in the holes 65a and fixed, the second transmission lines 62 are connected to the vacuum-side surface 63b of the light-transmissive member 63.

As described above, in the transmission apparatus 60 according to the second embodiment, the first fixing member 64 is directly attached to the partition of the vacuum chamber 24 without intervening the light-transmissive member 63. Since the light-transmissive member 63 made of silica glass or the like rarely breaks, it can be made as thin as possible. This can eventually suppress attenuation of light signals passing through the light-transmissive member 63 and largely improve the light signal transmission performance.

<Embodiment of Article Manufacturing Method>

An article manufacturing method according to the embodiment of the present invention is suitable to, for example, manufacture an article such as a micro device such as a semiconductor device or an element having a microstructure. The article manufacturing method according to this embodiment includes a step of forming a latent image pattern on a photoresist applied to a substrate using the above-described drawing apparatus (a step of performing drawing on a substrate), and a step of developing the substrate on which the latent image pattern is formed in the above-described step. The manufacturing method also includes other known steps (for example, oxidation, film formation, vapor deposition, doping, planarization, etching, resist removal, dicing, bonding, and packaging). The article manufacturing method according to this embodiment is more advantageous in terms of at least one of the performance, quality, productivity, and production cost of an article than the conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-183591 filed on Aug. 22, 2012, which is hereby incorporated by reference herein in its entirety.

What is claimed is:

1. A transmission apparatus for transmitting a light signal between an outside and an inside of a vacuum chamber, comprising:
a plurality of first transmission lines configured to transmit a plurality of light signals outside the vacuum chamber;
a plurality of second transmission lines configured to transmit the plurality of light signals inside the vacuum chamber; and
a light-transmissive member configured to transmit the light signals between the plurality of first transmission lines and the plurality of second transmission lines,
wherein the light-transmissive member has a structure formed to isolate light paths of the plurality of light signals between the plurality of first transmission lines and the plurality of second transmission lines from each other.

2. The apparatus according to claim 1, wherein the structure includes a trench.

3. The apparatus according to claim 2, wherein the trench is provided with a light-absorptive material.

4. The apparatus according to claim 2, wherein the trench is formed not to be exposed to a surface on a side of the plurality of first transmission lines out of surfaces of the light-transmissive member.

5. The apparatus according to claim 2, wherein the trench has a depth smaller than a thickness of the light-transmissive member.

6. The apparatus according to claim 1, further comprising:
a first fixing member configured to fix the plurality of first transmission lines to the light-transmissive member; and
a second fixing member configured to fix the plurality of second transmission lines to the light-transmissive member.

7. The apparatus according to claim 1, wherein the light-transmissive member is attached to a partition of the vacuum chamber so as to cover a through-hole formed in the partition.

8. A drawing apparatus for performing drawing on a substrate using a plurality of charged particle beams, comprising:
a vacuum chamber;
a transmission apparatus configured to transmit a light signal between an outside and an inside of said vacuum chamber; and
a charged particle optical system located in the vacuum chamber,
the transmission apparatus comprising:
a plurality of first transmission lines configured to transmit a plurality of light signals outside the vacuum chamber;
a plurality of second transmission lines configured to transmit the plurality of light signals inside the vacuum chamber; and
a light-transmissive member configured to transmit the light signals between the plurality of first transmission lines and the plurality of second transmission lines,
wherein the transmission apparatus transmits the light signal to the charged particle optical system.

9. The apparatus according to claim 8, wherein the charged particle optical system includes a blanking deflector configured to individually blank the plurality of charged particle beams, and
the transmission apparatus transmits the light signal to the blanking deflector.

10. A method of manufacturing an article, the method comprising:
performing drawing on a substrate using a drawing apparatus;
developing the substrate on which the drawing has been performed; and
processing the developed substrate to manufacture the article,
wherein the drawing apparatus, the apparatus performing drawing on substrates with a plural of charged particle beams, the apparatus comprising:
a vacuum chamber;
a transmission apparatus configured to transmit a light signal between an outside and an inside of said vacuum chamber; and
a charged particle optical system located in the vacuum chamber,
the transmission apparatus comprising:
a plurality of first transmission lines configured to transmit a plurality of light signals outside the vacuum chamber;
a plurality of second transmission lines configured to transmit the plurality of light signals inside the vacuum chamber; and
a light-transmissive member configured to transmit the light signals between the plurality of first transmission lines and the plurality of second transmission lines,
wherein the transmission apparatus transmits the light signal to the charged particle optical system.
